(19) United States
(12) Patent Application Publication
(10) Pub. No.: US 2025/0003112 A1
(43) Pub. Date: Jan. 2, 2025

(54) VIRTUAL SENSOR FOR PREDICTING AND MONITORING TEMPERATURE OF CHAMBER COMPONENTS

(71) Applicant: Applied Materials, Inc., Santa Clara, CA (US)

(72) Inventors: Ala MORADIAN, Sunnyvale, CA (US); Zhepeng CONG, San Jose, CA (US); Vishwas Kumar PANDEY, Madhya Pradesh (IN); Tao SHENG, Santa Clara, CA (US); Nimrod SMITH, Cupertino, CA (US); Karthik RAMANATHAN, Bangalore (IN); Manjunath SUBBANNA, Bangalore (IN)

(21) Appl. No.: 18/634,248

(22) Filed: Apr. 12, 2024

(30) Foreign Application Priority Data
Jun. 30, 2023 (IN) 202341043996

(51) Int. Cl. C30B 25/16; C30B 25/10; G01K 1/02; G01K 3/08

(52) U.S. Cl. CPC C30B 25/16; C30B 25/10; C30B 25/165; G01K 1/026; G01K 3/08

(57) ABSTRACT

A method and apparatus for virtually sensing a temperature of a hardware component of semiconductor processing chamber are disclosed. In one or more embodiments, a method of operation for a processing chamber suitable for use in semiconductor manufacturing includes receiving a process recipe for a manufacturing process and monitoring a first temperature of a first hardware component of the processing chamber using a sensor. The method further includes synthesizing, using a model of the processing chamber, a first virtual temperature of a second hardware component of the processing chamber based on the received process recipe and the first temperature of the first hardware component.

### RELATED APPLICATIONS

This application claims benefit from Indian Provisional Application Ser. No. 202341043996, filed Jun. 30, 2023, which is incorporated herein by reference in its entirety.

### BACKGROUND

### Field

Embodiments of the present disclosure generally relate to virtually sensing, predicting, and/or monitoring the temperature of hardware components, such as a top plate, in a deposition chamber. The deposition may be an epitaxial deposition chamber useful in semiconductor manufacturing.

### Description of the Related Art

Improved process control results in improved yield and quality during semiconductor manufacturing. To better control process results, it is helpful to control the temperature of chamber hardware components, such as a top plate, located within the chamber, as the hardware can radiate thermal energy to substrates and affect process results.

However, it is difficult to accurately measure the temperature of various hardware components. The difficulty in measuring temperatures of various hardware components is due to hardware constraints, such as location of the hardware or the material from which the hardware is composed. As an example, using similar materials can present challenges to measuring a temperature of certain components with an infrared pyrometer. Adjusting the material composition of certain components can add complexity to pyrometer calibration and also adds complexity to the design of the pyrometer, which increases the overall cost of the pyrometer and the deposition chamber.

Therefore, an improved system and methods for determining hardware temperatures, such as top plate temperatures, are needed.

### SUMMARY

Embodiments of the present disclosure generally relate to virtually sensing, predicting, and/or monitoring the temperature of hardware components, such as an isolation (e.g., top) plate, in a deposition chamber, such as an epitaxial deposition chamber useful in semiconductor manufacturing.

In one or more embodiments, a method of operation for a processing chamber suitable for use in semiconductor manufacturing includes receiving a process recipe for a manufacturing process and monitoring a first temperature of a first hardware component of the processing chamber using a sensor. The method further includes synthesizing, using a model of the processing chamber, a first virtual temperature of a second hardware component of the processing chamber based on the received process recipe and the first temperature of the first hardware component.

In one or more embodiments, a method of operation for a processing chamber suitable for use in semiconductor manufacturing, includes receiving a process recipe for a deposition process in the processing chamber and synthesizing a virtual temperature of an upper plate or a substrate support, and a virtual temperature of an isolation plate using a virtual model based on the received process recipe. The method further includes determining if a first difference between one or more temperature measurements of the upper plate or the substrate support and the synthesized virtual temperature of the upper plate or the substrate support is within a threshold. Responsive to the first difference being outside of the threshold, the method further includes adjusting the virtual model until the first difference is within the threshold, the adjusting of the virtual model includes adjusting the virtual temperature of the isolation plate.

In one or more embodiments, a computer readable medium includes storing instructions that when executed by a processor of a system, cause the system to receive a process recipe for a manufacturing process, monitor a first temperature of a first hardware component of a processing chamber using a sensor; and synthesize, using a model of the processing chamber, a first virtual temperature of a second hardware component of the processing chamber based on the received process recipe and the first temperature of the first hardware component.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross-sectional view of a processing chamber, according to one or more embodiments.

FIG. 2 illustrates a method related to temperature control during processing, according to one or more embodiments.

FIG. 3 illustrates example operations related to temperature control during processing, according to one or more embodiments.

FIG. 4 illustrates a method of operating a process chamber, according to one or more embodiments of the disclosure.

FIG. 5 illustrates an example processing system for training and/or utilizing a machine learning model to determine a temperature of a hardware component used in semiconductor manufacturing.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to systems, apparatus, and methods for monitoring hardware temperature for semiconductor manufacturing.

Embodiments of the present disclosure relate to real-time estimations (e.g., “virtual sensing”) of hardware temperature within a semiconductor processing system. For example, a virtual model, which encompasses or utilizes system modeling algorithms and processing chamber geometry, may be used to predict or estimate temperatures of hardware components, such as hardware that is difficult to directly measure during semiconductor processing. Measurements captured during past and/or current process runs may be used to estimate temperatures of hardware components and/or synthesize parameters to achieve a predetermined hardware component temperature. Machine learning algorithms (MLAs) may be incorporated to update the virtual model for improved accuracy. The MLA may utilize a physics-based model, a data-based model, or a combination of a physics-based or data-based model.

Methods for system modeling using a system modeling algorithm can utilize one or a combination of finite element modeling, finite volume modeling, finite difference modeling, fluid dynamics modeling (e.g., Navier-Stokes equations), process parameters, physics constraints (e.g., conservation of mass/energy equations), material qualities and dimensions, empirical data, and other factors, to model behavior of a processing system and environment. The model may solve for governing equations relevant to the processing chamber, such as fluid dynamics equations, energy equations, thermal equations, and electric/magnetic field equations. The model may also solve for estimated values of the temperature, thermal gradients, fluid flow, electrical charge, and magnetic field strength at various points within the processing system. The estimated equations and/or values from the system model facilitate determinations of certain operational aspects of the processing system. However, conventional models are challenging to employ on processing systems during processing, due to real-time changes in the processing system. Therefore, conventional models have inaccurate results. The disclosed embodiments address these challenges by one or both of 1) updating models using machine learning algorithms, or 2) utilizing real-time process data. In one non-limiting example, the aspects of the disclosure provide for estimation of a temperature of an isolation plate in epitaxial processing chambers. Mathematical techniques, such as proper orthogonal decomposition, balancing methods, and reduced basis methods may be utilized to reduce an order of the model and accelerate run time.

A neural network (e.g., MLA, as described herein) generally uses multiple inputs, such as from different sensors, to generate one or multiple outputs. The inputs can be taken at the same or different times as the outputs. The outputs may be simulated. The individual inputs (e.g., p_1, p_2, . . . , p_R) are weighted by the corresponding elements (e.g., w_{1,1}, w_{1,2}, . . . , w_{1,R}) of the weight matrix W. Each neuron has a bias b, which is summed with the weighted inputs to form the net input n=Wp+b. The net input n is then applied to a transfer function f. The transfer function can be a linear or nonlinear function of n. A particular transfer function is selected based on the problem to solve. Typical transfer functions are linear, hard limit, hyperbolic Tangent Sigmoid (tansig), Log-Sigmoid (logsig) or Competitive functions. The output of a neuron a can be defined as a=f(Wp+b).

A single-layer network of S neurons may operate over a vector of inputs p to generate an output a, while a combination of layers create a multilayer neural network. A layer whose output is the network output is the output layer. The other layers are called hidden layers. After the architecture is defined, the next step is training the multilayer neural network. The preferred training method is called backpropagation, which is a generalization of the Least Mean Square error or LMS algorithm. Backpropagation is an approximate steepest descent algorithm, in which the performance index is mean square error. The general operations of backpropogation are: propagate the inputs forward to the network, then calculate the sensitivities backward through the network and use the sensitivities to update the weights and biases using a steepest descent rule. The process is repeated until the objective function is minimized or a number of iterations is executed.

In the present solution, inputs may include measurements of one or more physical characteristics (such as temperature) of one or more processing chamber components (e.g., temperature measurements of a hardware component), one or more chemical characteristics of one or more processing chamber components, one or more process recipe parameters, and/or one or more stimulations. Outputs may include a temperature of a processing chamber component, such as a top plate. In one or more embodiments, a target top plate temperature may be utilized as an input, and process recipe parameters may be an output.

As described herein, a program may utilize both an MLA and one or more virtual models to determine an output of the program. The MLA and/or the virtual model within the program utilizes measured processing parameters to generate virtual or synthetic temperatures of processing chamber components that are difficult or impossible to measure directly. Stated otherwise, a combination of measured values and system modeling may be used to estimate a “virtual” temperature of an unmeasured (or unmeasurable) component. Measurements of one or more input data parameters (e.g., actual temperature measurements of hardware, gas flow rates, pressures, etc.) and one or more output data parameters (e.g., temperatures) may be used to train the program. The virtual model may include a virtual replica or a digital twin of the processing system. The training may occur in a test run environment, while the actual hardware is meant for use in a commercial fabrication environment. Training of the MLA improves accuracy of results. Accuracy is particularly improved in response to changing conditions within the processing system. For example, processing of the substrates, such as semiconductor substrates, within a system leads to degradation of hardware components. Degraded components include lamps, which can suffer reduced output, or plates, which can suffer reduced transparency. These degradations affect simulation accuracy relative to the physical processing chamber. However, aspects of the present disclosure provide for real-time updates to the program and/or the model via simulation confirmations and utilization of the MLA. The real-time updates provided for improved results.

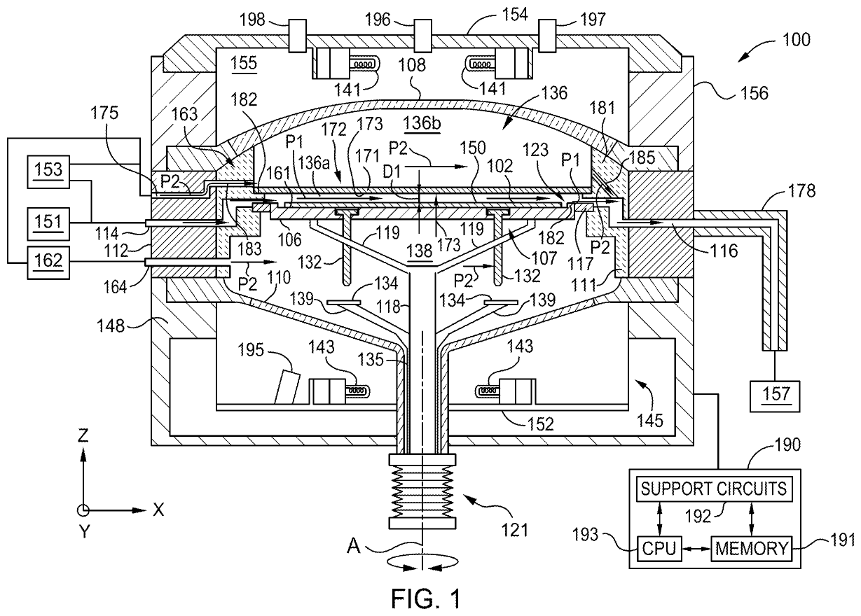

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window, for example an upper dome), a lower plate 110 (such as a lower window, for example a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate 108 and a lid 154. The plurality of upper heat sources 141 form a portion of the upper heat source module 155. The lid 154 includes a plurality of sensor devices 196, 197, 198 disposed therein or thereon. Each of the sensor devices 196, 197, 198 may be configured to measures one or more temperatures within the processing chamber 100. A lower sensor device 195 is configured to measure temperature(s) within the processing chamber 100. In one or more embodiments, each sensor device 195, 196, 197, 198 is a pyrometer. Each sensor device 195, 196, 197, 198 may be an optical sensor device, such as an optical pyrometer. The present disclosure contemplates that sensors other than pyrometers may be used. Each sensor device 195, 196, 197, 198 is a single-wavelength sensor device or a multi-wavelength (such as dual-wavelength) sensor device. The lower sensor device 195 is disposed adjacent to a floor 152 disposed within the lower body 148.

It is contemplated that the process chamber 100 may include any one, any two, or any three of the four illustrated sensor devices 195, 196, 197, 198. It is also contemplated that the process chamber 100 may include one or more additional sensor devices, in addition to the sensor devices 195, 196, 197, 198. The process chamber 100 may include sensor devices disposed at different locations and/or with different orientations than the illustrated sensor devices 195, 196, 197, 198.

The plurality of lower heat sources 143 are disposed between the lower plate 110 and a floor 152. The plurality of lower heat sources 143 form a portion of a lower heat source module 145. The upper plate 108 is an upper dome and/or is formed from a substantially transmissive material, such as an energy transmissive material or a radiation transmissive material, such as quartz. The lower plate 110 is a lower dome and/or is also formed from an energy transmissive material, such as quartz.

An upper volume 136 and a purge volume 138 are formed between the upper plate 108 and the lower plate 110. The upper volume 136 and the purge volume 138 are part of an internal volume defined at least partially by the upper plate 108, the lower plate 110, and one or more liners 111, 163.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 optionally includes lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a second shaft 135 disposed around the shaft 118.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

A plate 171 (also referred to as a top plate or isolation plate) having a first face 172 and a second face 173 opposing the first face 172, is positioned between the upper plate 108 and the substrate support 106. In one or more embodiments, the plate 171 is formed from quartz. In one or more embodiments, the plate 171 is part of a flow guide structure. The second face 173 faces the substrate support 106. The processing chamber 100 includes the one or more liners 111, 163. An upper liner 163 includes an annular section 181 and one or more ledges 182 extending inwardly relative to the annular section 181. The one or more ledges 182 are configured to support one or more outer regions of the second face 173 of the plate 171. The upper liner 163 includes one or more inlet openings 183 and one or more outlet openings 185. In one or more embodiments, the plate 171 is in the shape of a disc, and the annular section 181 is in the shape of a ring. The plate 171 can be in the shape of a rectangle. The plate 171 divides the upper volume 136 between the substrate support 106 and the upper plate 108 into a lower portion 136a and an upper portion 136b. The lower portion 136a is a processing portion. In one or more embodiments, the plate 171 is an isolation plate that at least partially (such as partially or completely) fluidly isolates the upper portion 136b from the lower portion 136a.

Due to the relatively close position of the plate 171 to the substrate 102 during processing, the plate 171 affects the temperature of the substrate 102. The plate 171 may also affect a temperature of the gaseous precursors flowed across the substrate 102. Therefore, the activation or depletion of the gaseous precursors is also impacted. The temperature of the gaseous precursors also impacts the growth rate on the substrate 102, the selectivity of epitaxial growth on the substrate 102, the dopant density, or a film quality. Thus, controlling the temperature of the plate 171 within a predetermined operation plate facilitates improved processing uniformity, such as deposition uniformity. To control the temperature of the plate 171 within an operational plate, it is helpful to first determine the temperature of the plate 171. However, as each of the plate 171, the upper plate 108, and the lower plate are made out of quartz, sensors 195-198 can be unable to determine the temperature of the plate 171. However, aspects of the present disclosure provide for virtual sensing of the plate 171 temperature, thereby improving processing.

The flow module 112 (which can be at least part of a sidewall of the processing chamber 100) includes the one or more gas inlets 114 in fluid communication with the lower portion 136a. The flow module 112 includes one or more second gas inlets 175 in fluid communication with the upper portion 136b. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the lower portion 136a to flow over the substrate 102. During the deposition operation, one or more purge gases P2 flow through the one or more second gas inlets 175, through the one or more inlet openings 183 of the lower liner 111, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 163 and the lower liner 111, and through the one or more gas exhaust outlets 116. The one or more purge gases P2 are exhausted through the one or more outlet openings 185, through the same gaps between the upper liner 163 and the lower liner 111, and through the same one or more gas exhaust outlets 116 as the one or more process gases P1. The present disclosure contemplates that one or more purge gases P2 can be separately exhausted through one or more second gas exhaust outlets that are separate from the one or more gas exhaust outlets 116.

The present disclosure also contemplates that the one or more purge gases P2 can be supplied to the purge volume 138 (through the one or more purge gas inlets 164) during the deposition operation, and exhausted from the purge volume 138.

During a cleaning operation, one or more cleaning gases flow through the one or more gas inlets 114, through the one or more gaps (between the upper liner 163 and the lower liner 111), and into the lower portion 136a. During the cleaning operation, one or more cleaning gases also simultaneously flow through the one or more second gas inlets 175, through the one or more inlet openings 183 of the upper liner 163, and into the upper portion 136b. The present disclosure contemplates that the one or more cleaning gases used to clean surfaces adjacent the upper portion 136b can be the same as or different than the one or more cleaning gases used to clean surfaces adjacent the lower portion 136a.

The processing chamber 100 facilitates separating the gases provided to the lower portion 136a from the gases provided to the upper portion 136b, which facilitates parameter adjustability. Additionally, one or more purge gases and one or more cleaning gases can be separately provided to the upper portion 136b to facilitate reduced contamination of the upper plate 108 and/or the plate 171.

As shown, a controller 190 is in communication with the processing chamber 100 and is used to control processes and methods, such as the operations of the methods described herein.

The controller 190 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the plate 171 and/or the one or more liners 111, 163); and/or sensors that monitor temperatures of the substrate 102, the substrate support 106, the plate 171, and/or the liners 111, 163. The controller 190 is equipped with or in communication with a system model of the processing chamber 100. The system model is a program or series of algorithms configured to estimate parameters (such as a gas flow rate, a gas pressure, a processing temperature, a rotational position of component(s), a heating profile, a coating condition, and/or a cleaning condition) within the processing chamber 100. The system model estimates parameters throughout a deposition operation and/or a cleaning operation. The controller 190 is further configured to store readings, calculations, and user-input data. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100. As such, aspects of the controller, or applications executed thereby, function as an operation improvement engine.

The controller 190 facilitates monitoring of system conditions, estimates parameters, controls processing operations or recipe parameters, generates an alert on a display, halts a deposition operation, initiates a chamber downtime period, delays a subsequent iteration of the deposition operation, initiates a cleaning operation, halts the cleaning operation, adjusts a heating power, and/or otherwise adjusts the process recipe.

The controller 190 may be for a specific process chamber, a set of process chambers, or a semiconductor processing tool as a whole. The controller 190 is configured to run a program which includes both the MLA and a virtual model of the process chamber. The virtual model may be a digital twin or a virtual sensor model. The program and the virtual model may be run to estimate and edit a process on a sub-portion of a process chamber, a single process chamber, a semiconductor processing tool, or a semiconductor fabrication facility. The program may be run on a controller at any level of a semiconductor fabrication facility or may be run on a cloud or metaverse.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters, simulations, and machine learning algorithms are stored in the memory 191 as software routines that are executed or invoked to turn the controller 190 into a specific purpose controller to control the operations of the various chambers/modules described herein. The controller 190 is configured to conduct any of the operations described herein. While embodiments herein describe certain aspects as stored locally on memory 191, it is contemplated that one or more aspects may be stored remotely and accessed via a data connection.

In one or more embodiments, which can be combined with other embodiments, the controller 190 includes a mass storage device, an input control unit, and a display unit. The controller 190 monitors the temperature of the substrate 102, the temperature of the substrate support 106, the temperature of the plate 171, the process gas flow, and/or the purge gas flow. In one or more embodiments, the controller 190 includes multiple controllers 190, such that the stored readings and calculations and the system model are stored within a separate controller from the controller 190, which controls the operations of the processing chamber 100. In one or more embodiments, all of the system model and the stored readings and calculations are saved within the controller 190.

The controller 190 is configured to control the sensor devices 195, 196, 197, 198, the deposition, the cleaning, the rotational position, the heating, gas flow through the processing chamber 100, and other operations, by providing instructions or control signals to various components of the system. The controller 190 is configured to adjust the output to the controls based on the sensor readings, the system model, and the stored readings and calculations, all of which may interact with or be updated by MLA or other software applications. The MLA may implement, adjust and/or refine one or more algorithms, inputs, outputs or variables described herein. Additionally or alternatively, the MLA may rank or prioritize certain aspects of adjustments of the process chamber 100 or methods described herein. The MLA may account for other changes within the processing systems such as hardware replacement and/or degradation. In one or more embodiments, the MLA accounts for upstream or downstream changes that may occur in the processing system due to variable changes of the process chamber 100. For example, if variable “A” is adjusted to cause a change in aspect “B” of the process, and such an adjustment unintentionally causes a change in aspect “C” of the process, then the MLA may take such a change of aspect “C” into account. In such an embodiment, the one or more machine learning algorithms and/or artificial intelligence algorithms embody predictive aspects related to implementing the process chamber 100.

In one or more embodiments, the controller 190 automatically conducts the operations described herein without the use of one or more machine learning algorithms or artificial intelligence algorithms. In one or more embodiments, the controller 190 compares measurements (such as of a reading increase and/or a reading decrease) to data in a look-up table and/or a library, to determine if the coating condition and/or the cleaning condition are detected. The controller 190 can stored measurements as data in the look-up table and/or the library.

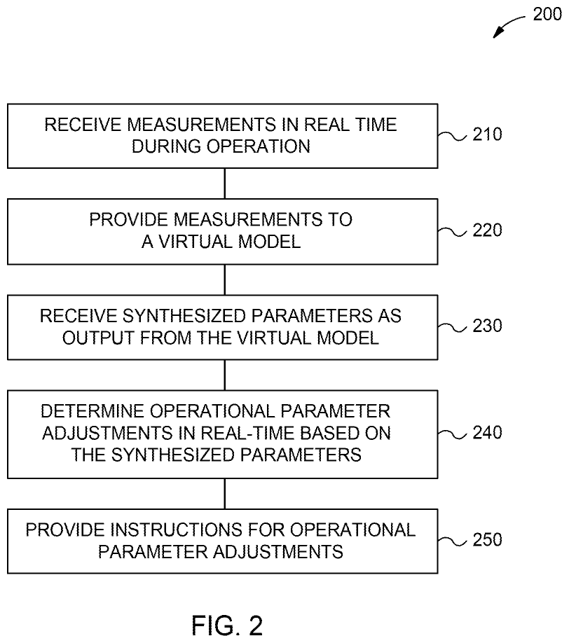

FIG. 2 illustrates a method 200 related to real-time estimation of process chamber hardware temperature, according to one or more embodiments. The method 200 may, for example, be performed by applications or algorithms described herein, such one or more programs using the MLA, the virtual model, or other applications. The method 200 may be implemented using one or more computing systems, such as one or more processors and a non-transitory computer readable medium comprising instructions for performing techniques described herein.

The method 200 begins at an operation 210, where real-time processing parameter measurements are received from a processing chamber (e.g., sensors 195-198 from processing chamber 100). The measurements may, for example, comprise a temperature of the upper plate 108, a temperature the lower plate 110, a temperature of the substrate support 106, or a temperature of the substrate 102. Parameters measured may not include a temperature of the plate 171, as this is provided by the virtual model.

At an operation 220, the measurements are provided to the virtual model of the processing chamber.

At an operation 230, synthesized parameters are received as output from the virtual model. For example, the virtual model may synthesize the temperature of the plate 171, in view of historical and/or training data. At least some of synthesized parameters are different parameters from the parameters that were measured. For example, the virtual model may synthesize top plate temperature based on measured temperatures within the process chamber 100, as well as based on one or more known or estimated operational characteristics, such as temperature, pressure, flow rate, and the like.

Training data and the virtual model may be initially established empirically. For example, correlations between sensor measurements (such as measurements from sensors 195-198) can be determined to allow synthesizing of the plate 171 temperature. While these correlations may not be determined during substrate processing, other methodologies allow for creation of a model. For example, a pyrometer may be placed within the processing system at a location to allow for measurement of the plate 171, while avoiding interference from the upper plate 108 or the plate 110. Such a configuration may adversely affect deposition uniformity, but is sufficient for establishing a baseline relationship when using a test substrate in a non-commercial-fabrication site. Additionally or alternatively, it is contemplated that aspects of U.S. patent application Ser. No. 18/132,861 filed Apr. 10, 2023 (which is herein incorporated by reference) may be used to establish a baseline relationship for algorithms and models herein.

At an operation 240, processing parameter adjustments are determined in real-time based on the synthesized parameters. For example, process recipe conditions are adjusted to achieve a target temperature of the plate 171, thus improving deposition uniformity. Process recipe conditions that can be adjusted include, but are not limited to, gas flow rate, gas composition, heater outputs (e.g., lamp outputs), substrate support position, exhaust flow rate, top plate blower motor output, and the like.

At an operation 250 instructions, including the adjusted processing parameters, are provided to the processing chamber 100. In one or more embodiments, real-time measurements are continuously performed, and real-time adjustments are continuously made, according to method 200.

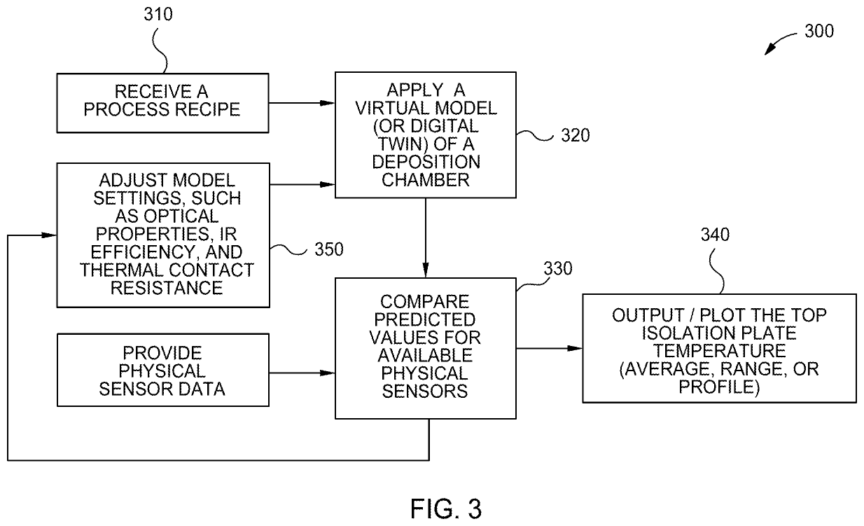

FIG. 3 illustrates example operations related to temperature control during processing, according to one or more embodiments. The operations 300 include inputting a process recipe of a deposition or cleaning process that is to be performed in the processing chamber 100, in sub-operation 310. The process recipe includes variables such as substrate position, heater output (e.g., lamp output), pressure, temperature, gas flow rate, gas composition, and the like.

The process recipe is input into a virtual model of a processing chamber 100, in sub-operation 320. The processing chamber 100 may be a deposition chamber, such as an epitaxial deposition chamber. In response, algorithms of the virtual model synthesize (or estimate) predetermined output values, corresponding to a state of the processing chamber 100. For example, the output may include one or more of a temperature of a top plate (e.g., an isolation plate), a temperature of an upper plate, a temperature of a lower plate, and a temperature of a substrate support.

In sub-operation 330, at least some output from sub-operation 320 is compared to measured sensor data from a physical processing chamber corresponding to the virtual model. The measured sensor data is proved during a sub-operation 315. The sub-operation 315 may be performed either before, after, or simultaneously with the provision of the virtually modeled data from sub-operation 320. For example, a temperature of an upper plate, a temperature of a lower plate, and/or a temperature of a substrate support are measured by sensors within the physical processing chamber and compared to an output of the virtual model. The comparison allows for confirmation of the accuracy of the virtual model. The comparison of synthesized values from the virtual model with actual measured data from the physical model provides an indirect means to confirm that the remaining data output by the virtual model is accurate. In particular, the top plate temperature (which generally may not be directly measured during processing) may be estimated as being accurate if temperatures of other components adjacent to the top plate are accurate.

If the comparison in sub-operation 330 generates a difference less than a threshold, meaning the virtual is within a predetermined accuracy tolerance, then operation 300 proceeds to sub-operation 340. The threshold can be a predetermined threshold. The threshold can be a threshold value. The predetermined threshold can be selected, for example, by a user and/or the controller described herein. For example, the user and/or the virtual model described herein can select and/or update the predetermined threshold. In sub-operation, 340, data indicative of a temperature of a top plate is output to a controller or memory, and/or the data is output to a user or operator, for example, on a display screen. The data can be plotted in the controller or memory, and/or the data can be plotted on the display screen. The output may include an average top plate temperature, a profile of the top plate temperature, or a range of temperatures of the top plate. The output may be specific to a particular time during substrate processing or during a cleaning operation. For example, the output may be operator-selected to correspond to pre-heating, to cleaning, to deposition, or to a particular processing during (e.g., 2 minutes into a process run). It is contemplated that the output can be generated at different operator-selected intervals, including prior to substrate deposition, post substrate deposition, or during substrate deposition.

Returning to sub-operation 330, if the difference(s) between one or more measured values and one or more predicted values exceed the threshold, then the operation proceeds to sub-operation 350. In sub-operation 350, a program utilizes an MLA to adjust one or more model parameters, such as optical properties of the upper plate or lower plate, heater output (e.g., lamp output) efficiency, thermal contact resistance, and the like. The program and/or the MLA may use data received from physical sensors of the processing chamber when determining which model parameters are to be adjusted to fit the virtual model more closely to the physical chamber. After updating the virtual model in sub-operation 350 to create an adjusted virtual model, operation 300 returns to sub-operation 320. Operation 300 continues until sub-operation 340 is completed. If sub-operation 340 is not completed after a predetermined time, then an error message is generate for an operator.

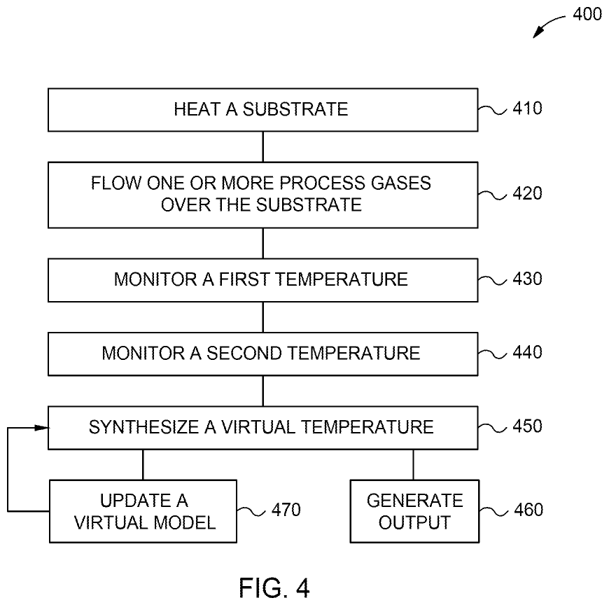

FIG. 4 illustrates a method 400 of operating a process chamber, according to one or more embodiments. The method 400 begins at an operation 410, in which a substrate within a processing chamber is heated to a predetermined processing temperature, according to a process recipe. In an operation 420, one or more process gases are introduced into the process chamber to flow over the heated substrate, according to the process recipe. In an operation 430, a first temperature within the processing chamber is monitored, for example, by measurement using a sensor. In one or more embodiments, the sensor is a pyrometer which measures the temperature of an upper plate (e.g., an upper window) within the processing chamber.

In an operation 440, a second temperature within the processing chamber is monitor by measurement with a sensor. For example, the sensor is a pyrometer which measures the temperature of a substrate support within the process chamber. In an operation 450, a virtual model of the processing chamber synthesizes a virtual temperature of an unmeasured component of the physical processing chamber. For example, the virtual model synthesizes a temperature of a plate, such as the plate 171, within the process chamber. Additionally, in operation 450, the virtual model synthesizes temperatures corresponding measured components (e.g., monitored temperatures in operations 430 and 440). If the synthesized temperatures of the measured components are within the threshold (such as a predetermined tolerance of the measured values of the physical processing chamber), then output is generated in an operation 460. The comparison of the synthesized values to the measured values confirms the accuracy of the virtual model. The output at operation 460 is indicative of the synthesized temperature of the top plate. The output can display one or more of the synthesized temperatures, such as to a user on a display. The output can save one or more of the synthesized temperatures to the memory. As an example, the output can label the one or more of the synthesized temperatures as “accepted” for future use, such as future virtual model operations and/or future substrate processing operations.

If the synthesized temperatures are outside of the threshold (such as the predetermined tolerance of the measured values), then the method 400 proceeds to an operation 470. During the operation 470, one or more parameters of the virtual model are updated using a MLA. The adjusting of the virtual model includes adjusting one or more of the virtual temperatures of the upper plate, the substrate support, and/or the isolation plate to create one or more refined virtual temperatures of the upper plate, the substrate support, and/or the isolation plate. In one or more embodiments, the virtual temperature of the isolation plate (which can be predicted) is adjusted. Subsequently, method 400 returns to operation 450, and method 400 proceeds until an output is generated in operation 460. Operation 470 can include deleting (or foregoing saving) the one or more of the synthesized temperatures. The output can save one or more of the synthesized temperatures to the memory. As an example, the output can label the one or more of the synthesized temperatures as “rejected” for future use.

While method 400 is illustratively described with respect to measuring the upper plate and the substrate support temperatures in operations 430 and 440, other hardware component measurements are also contemplated. It is noted that the upper plate and the substrate support temperatures provide beneficial reference data points for confirming virtual model accuracy, due to the physical proximity of the upper plate and the substrate support temperatures relative to the top plate. Specifically, a temperature gradient can exist between the substrate support (which readily absorbs thermal radiation from the lamps) and the top plate (which partially absorbs thermal radiation from each of the lamps, the substrate support, and the substrate disposed on the substrate support). Therefore, the temperature of the top plate is generally between that of the upper plate and the substrate support temperatures. If the virtual model synthesizes a temperature of the top plate outside of the gradient, inaccuracy of the virtual model can readily be determined.

The present disclosure contemplates that one or more operations of the methods described herein can be omitted. As an example, operation 470 and/or operation 460 can be omitted from the method 400.

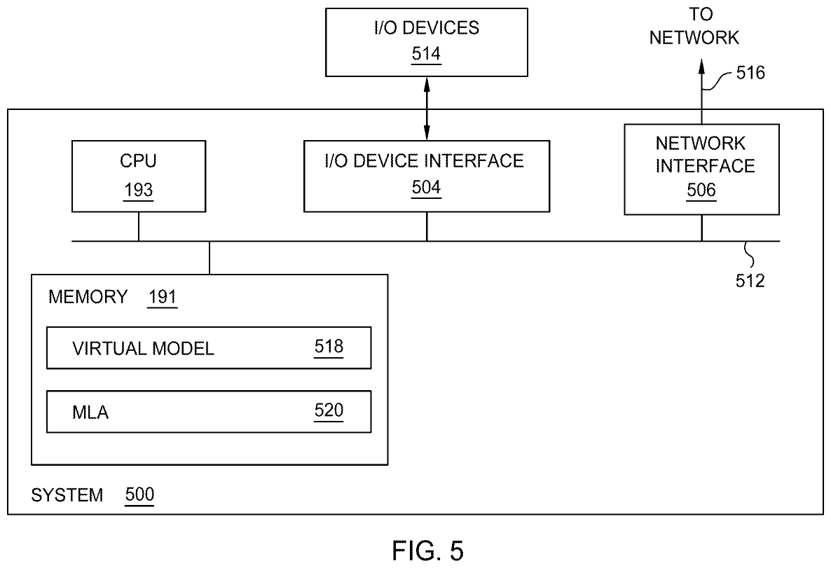

FIG. 5 illustrates an example computer system 500 used for real-time virtual temperature sensing, according to one or more embodiments. In one example, the computer system 500 may be (or may be used in place of) the controller 190 of FIG. 1. As shown, the system 500 includes a central processing unit (CPU) 193, one or more I/O device interfaces 504 that may allow for the connection of various I/O devices 514 (e.g., keyboards, displays, mouse devices, pen input, sensors, pyrometers, etc.) to the system 600, a network interface 506, a memory 191, and one or more interconnects 512.

As shown, memory 191 includes a virtual model 518 of a physical processing chamber, and a machine learning algorithm (MLA) 520 (which may be embedded on a neural network). The MLA 520 stored on the memory 191 perform one or more of the methods and operations described above with respect to FIGS. 1-4. For example, the virtual model 518 and the MLA facilitate synthesizing of a virtual temperature for a top plate of the physical processing chamber. The system 500 may use the synthesized parameters to provide instructions and information to the processing chamber, to provide output to a display, or to refine the virtual model 518. The virtual model includes a refined transparency value of the upper plate, and/or a refined heater output value.

While embodiments herein are described with respect to synthesizing temperatures, it is noted that other metrics may be synthesized. Moreover, it is noted that other hardware components may be subject to synthetic metrology determinations. For example, process kits, liners, substrate supports, preheat rings, and other hardware components, may have temperatures (or other metrics) synthesized according to aspects described herein.

The methods disclosed herein comprise one or more operations or actions for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or a processor. Generally, where there are operations illustrated in figures, those operations may have corresponding counterpart means-plus-function components with similar numbering.

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

A processing system may be implemented with a bus architecture. The bus may include any number of interconnecting buses and bridges depending on the specific application of the processing system and the overall design constraints. The bus may link together various circuits including a processor, machine-readable media, and input/output devices, among others. A user interface (e.g., keypad, display, mouse, joystick, augmented reality, virtual reality, etc.) may also be connected to the bus. The bus may also link various other circuits such as timing sources, peripherals, voltage regulators, power management circuits, and other types of circuits, which are well known in the art, and therefore, will not be described any further. The processor may be implemented with one or more general-purpose and/or special-purpose processors. Examples include microprocessors, microcontrollers, DSP processors, and other circuitry that can execute software. Those skilled in the art will recognize how best to implement the described functionality for the processing system depending on the particular application and the overall design constraints imposed on the overall system.

If implemented in software, the functions may be stored or transmitted over as one or more instructions or code on a computer-readable medium. Software shall be construed broadly to mean instructions, data, or any combination thereof, whether referred to as software, firmware, middleware, microcode, hardware description language, or otherwise. Computer-readable media include both computer storage media and communication media, such as any medium that facilitates transfer of a computer program from one place to another. The processor may be responsible for managing the bus and general processing, including the execution of software modules stored on the computer-readable storage media. A computer-readable storage medium may be coupled to a processor such that the processor can read information from, and write information to, the storage medium. In the alternative, the storage medium may be integral to the processor. By way of example, the computer-readable media may include a transmission line, a carrier wave modulated by data, and/or a computer readable storage medium with instructions stored thereon separate from the wireless node, all of which may be accessed by the processor through the bus interface. Alternatively, or in addition, the computer-readable media, or any portion thereof, may be integrated into the processor, such as the case may be with cache and/or general register files. Examples of machine-readable storage media may include, by way of example, RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The machine-readable media may be embodied in a computer-program product.

A software module may include a single instruction, or many instructions, and may be distributed over several different code segments, among different programs, and across multiple storage media. The computer-readable media may comprise a number of software modules. The software modules include instructions that, when executed by an apparatus such as a processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into a cache to increase access speed. One or more cache lines may then be loaded into a general register file for execution by the processor. When referring to the functionality of a software module, it will be understood that such functionality is implemented by the processor when executing instructions from that software module.

Benefits of the present disclosure include accurate monitoring and adjustment (e.g., optimizing) of process parameters of process recipes; adjustment of process parameters of process recipes that account for aging and wear of chamber components; and adjustment of process parameters of process recipes in a manner that is real-time and in-situ. Benefits also include accurate and efficient prediction of measurements

It is contemplated that one or more aspects disclosed herein may be combined. As an example, one or more aspects, features, components, operations and/or properties of the processing chamber 100, the method 200, the operations 300, the method 400, and/or the computer system 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method of operation for a processing chamber suitable for use in semiconductor manufacturing, comprising:
receiving a process recipe for a manufacturing process;
monitoring a first temperature of a first hardware component of the processing chamber using a sensor; and
synthesizing, using a model of the processing chamber, a first virtual temperature of a second hardware component of the processing chamber based on the received process recipe and the first temperature of the first hardware component.

2. The method of claim 1, further comprising:
synthesizing, using the model, a second virtual temperature of the first hardware component; and
determining if a first difference between the first temperature of the first hardware component and the second virtual temperature is within a threshold, and
responsive to the first difference being outside of the threshold, adjusting the model until the first difference is within the threshold.

3. The method of claim 2, wherein the adjusting the model comprises updating the first virtual temperature.

4. The method of claim 2, further comprising:
monitoring a second temperature of a third hardware component of the processing chamber using a sensor;
synthesizing, using the model, a third virtual temperature of the third hardware component; and
determining if a second difference between the second temperature of the third hardware component and the third virtual temperature is within the threshold, and
responsive to the second difference being outside of the threshold, adjusting the model until the second difference is within the threshold.

5. The method of claim 1, wherein the monitoring the first temperature of the first hardware component is conducted during:
heating a substrate; and
flowing a process gas over the substrate.

6. The method of claim 4, wherein the first hardware component is one of an upper plate or a substrate support of the processing chamber, the second hardware component is an isolation plate of the processing chamber, and the third hardware component is another the upper plate of the substrate support.

7. The method of claim 6, wherein the upper plate and the isolation plate are formed from quartz.

8. The method of claim 2, wherein the first virtual temperature is updated using a machine learning algorithm.

9. A method of operation for a processing chamber suitable for use in semiconductor manufacturing, comprising:
receiving a process recipe for a deposition process in the processing chamber;
synthesizing a virtual temperature of an upper plate or a substrate support, and a virtual temperature of an isolation plate using a virtual model based on the received process recipe; and
determining if a first difference between one or more temperature measurements of the upper plate or the substrate support and the synthesized virtual temperature of the upper plate or the substrate support is within a threshold, and
responsive to the first difference being outside of the threshold, adjusting the virtual model until the first difference is within the threshold, the adjusting of the virtual model comprising adjusting the virtual temperature of the isolation plate.

10. The method of claim 9, further comprising:
if the first difference is outside of the threshold, synthesizing a refined virtual temperature for each of the upper plate, the substrate support, and the isolation plate based on the adjusted virtual model.

11. The method of claim 9, further comprising adjusting a processing parameter of the processing chamber if the first difference is within the threshold, wherein the adjusted processing parameter of the processing chamber comprises one or more of a gas flow rate, a substrate support position, or a heater output.

12. The method of claim 11, wherein the isolation plate is positioned between the upper plate and the substrate support, and the upper plate and the isolation plate are formed from quartz.

13. The method of claim 12, wherein the virtual model is updated using a machine learning algorithm.

14. The method of claim 10, wherein the virtual model includes a refined transparency value of the upper plate, or a refined heater output value.

15. The method of claim 9, further comprising:
determining if a second difference between one or more temperature measurements of the substrate support and the synthesized virtual temperature of the substrate support is within the threshold, and if the second difference is outside of the threshold, adjusting the virtual model until the second difference is within the threshold.

16. A non-transitory computer readable medium, storing instructions that when executed by a processor of a system, cause the system to:
receive a process recipe for a manufacturing process;
monitor a first temperature of a first hardware component of a processing chamber using a sensor; and
synthesize, using a model of the processing chamber, a first virtual temperature of a second hardware component of the processing chamber based on the received process recipe and the first temperature of the first hardware component.

17. The non-transitory computer readable medium of claim 16, wherein the instructions further cause the system to:
synthesize, using the model, a second virtual temperature of the first hardware component; and
determine if a first difference between the first temperature of the first hardware component and the second virtual temperature is within a threshold, and
responsive to the first difference being outside of the threshold, adjust the model until the first difference is within the threshold.

18. The non-transitory computer readable medium of claim 17, wherein the instructions further cause the system to:
monitor a second temperature of a third hardware component of the processing chamber using a sensor;
synthesize, using the model, a third virtual temperature of the third hardware component; and
determine if a second difference between the second temperature of the third hardware component and the third virtual temperature is within the threshold, and
responsive to the second difference being outside of the threshold, adjust the model until the second difference is within the threshold.

19. The non-transitory computer readable medium of claim 17, wherein the instructions further cause the system to:
adjust a processing parameter of the processing chamber responsive to the first difference being within the threshold, wherein the adjusted processing parameter of the processing chamber comprises one or more of a gas flow rate, a substrate support position, or a heater output.

20. The non-transitory computer readable medium of claim 17, wherein the adjusting the model comprises updating one or more of a transparency value of a heater output value.
